(19) United States
(12) Patent Application Publication
(10) Pub. No.: US 2004/0214431 A1
(43) Pub. Date: Oct. 28, 2004

(54) ELECTROPOLISHING ENDPOINT DETECTION METHOD

(76) Inventors: Jia-Min Shieh, Yunlin (TW); Shih-Chieh Chang, Taipei (TW); Bau-Tong Dai, Hsinchu Hsien (TW); Ying-Hao Li, Hsinchu (TW); Kwo-Hung Shen, Taipei (TW)

Correspondence Address: JIANQ CHYUN INTELLECTUAL PROPERTY OFFICE, 7 FLOOR-1, NO. 100, ROOSEVELT ROAD, SECTION 2, TAIPEI, 100, TW

(21) Appl. No.: 10/248,836

(22) Filed: Feb. 24, 2003

(30) Foreign Application Priority Data
Feb. 25, 2002 (TW) 91103246

(51) Int. Cl. H01L 21/302; H01L 21/461

(52) U.S. Cl. 438/689

(57) ABSTRACT

An electropolishing process endpoint detection method is described. The method is applicable to the electropolishing of a metal layer under a fixed current or voltage, wherein a voltage current detector is installed in the electropolishing apparatus. When the electropolishing process is proceeded to the barrier layer, a noticeable change occurs to the electric current or electric voltage because the resistance of the barrier layer is different from that of the metal layer. Based on the change in the saturated current or voltage, the endpoint of the electropolishing process is detected. Further, the voltage or current supply is discontinued by feedback controlling the current or voltage and the electropolishing action is terminated.

### CROSS REFERENCE TO RELATED APPLICATIONS

This application claims the priority benefit of Taiwan application serial no. 91103246, filed Feb. 25, 2002.

### BACKGROUND OF INVENTION

1. Field of Invention

The present invention is related to a semiconductor planarization process. More particularly, the present invention is related to an endpoint detection method for an electropolishing process.

2. Description of Related Art

Among the various semiconductor manufacturing techniques, surface planarization is one important technique for high density photolithography. A planarized surface prevents the scattering of the exposure light to effectively transfer a dense conductive line pattern. To provide a refined planarization for wafer is thus an important issue in semiconductor device manufacturing. Even in recent years, chemical mechanical polishing (CMP) remains a common practice for wafer planarization in a semiconductor process. A major reason is because the chemical mechanical polishing technique is an anisotropic type of polishing. Beside being able to provide a global planarization for a wafer surface, chemical mechanical polishing is also applicable for the manufacturing of horizontal and vertical metal interconnects of a damascene structure, the manufacturing of shallow trench isolation structures in the front end process and advanced devices, the planarization of micro electronic systems and the manufacturing of flat screen monitors.

However, when chemical mechanical polishing process is being used in the planarization of a glass insulation layer or a metal conductive line (copper damascene structure), problems, such as, pattern effect, remove selectivity, metal line dishing effect, scratch, oxide erosion and chemical mechanical polishing post-clean, etc. need to be addressed and overcome. Further, a new process is required for the manufacturing of the future 12 inch wafer and to accommodate the low stress demand of a low dielectric constant (low K) material.

An electropolishing process can result with less scratch, less microparticles, less waste slurry (lower solvent cost), higher etching rate (high productivity) compared to a chemical mechanical polishing process. Further, no pressure is needed to apply on the substrate. Therefore, electropolishing is the newest alternative for a planarization process. When electropolishing is used to planarize an electroplated copper, the metal surface can be evenly melted to provide the copper layer a planarized and shinny surface. When a two-step chemical mechanical polishing process is performed to form a copper damascene structure, electropolishing process replaces the first-step chemical mechanical polishing process in the removal of the copper layer until the barrier layer is exposed. The second-step chemical mechanical polishing is then performed to remove portions of the metal layer and the barrier layer until the surface of the dielectric layer is exposed. Not only the problem of scratching the copper layer surface by slurry is prevented, the planarization effect of the second-step chemical mechanical polishing is enhanced. However, to accurately control the time to switch between the two polishing processes is very important. If the time to switch between the two processes can not be accurately controlled, the electroplated copper in the via and the trench is excessively removed to induce the problem of dishing. Dishing, not only would influence the planarity of a substrate surface, it would also adversely affect the back-end process. Currently, there is no study that is directed to an endpoint detection method for a copper electropolishing process.

### SUMMARY OF INVENTION

Accordingly, the present invention provides an end-point detection method for an electropolishing process. As the electropolishing process proceeds to the junction between the metal layer and the barrier layer at the periphery of a pattern, a noticeable change would occur to the real time bias current of the electropolishing process, which indicates the endpoint of the electropolishing process has attained.

Accordingly, the present invention provides an endpoint detection method for an electropolishing process, wherein the method provides a substrate and this substrate comprises at least a first material layer and a second material layer. The first material layer comprises at least an opening, and the second material layer fills the opening and covers the first material layer. Thereafter, the substrate is placed in an electropolishing apparatus, and a fixed voltage is provided to the substrate to perform electropolishing on the second material layer. Thereafter, the electric value of the substrate is monitored in real time to detect the electropolishing endpoint.

Since the material of the first material layer is different from that of the second material layer, the first layer serves as the electropolishing endpoint layer for the second material layer. When a noticeable change occurs to the electric value of the substrate is detected, the electropolishing process has proceeded to the first material layer. The supply of electric voltage to the substrate is promptly discontinued and the electropolishing process is terminated.

The present invention further provides an electropolishing endpoint detection method, which is applicable to an electropolishing device, wherein the electropolishing device comprises at least an electrolytic tank, a power supply, and an endpoint detection device. This method provides a substrate, and this substrate comprises at least a first material layer and a second material layer. The first material layer comprises at least an opening, and the second material layer fills the opening and covers the first material layer. Thereafter, a substrate is placed in the tank and a fixed voltage is provided to the substrate by the power supply to perform electropolishing on the second material layer. The electric value of the substrate is detected to monitor the electropolishing endpoint using the endpoint detection device.

Since the material of the first material layer is different from that of the second material layer, the first material layer serves as the electropolishing endpoint layer for the second material layer. When the endpoint detection device detects a noticeable change in the electric value of the substrate, the electropolishing process has proceeded to the first material layer. The power supply then immediately ceases to operate to terminate the electropolishing process. Further, to accurately detect the endpoint of the electropolising process, a small signal modulator can be added to the endpoint detection device to enhance the sensitivity of the endpoint detection device.

The present invention further provides an endpoint detection method for an electropolishing process, wherein this method provides a substrate, and this substrate comprises a dielectric layer having an opening therein, a barrier layer and a metal layer sequentially formed thereon. An electropolishing process is performed on the metal layer and the electric value of the substrate is detected in real time. When a noticeable change occurs to an electric value, the electropolishing process has proceeded to the barrier layer and the endpoint of the process has attained.

Since the resistance of the barrier layer is different from that of the metal layer, the barrier layer serves as the electropolishing endpoint layer. When a noticeable change occurs to the electric value of the substrate, the electropolishing process has proceeded to the barrier layer. In other words, the electropolishing process has reached the endpoint and can be terminated.

The endpoint detection method of the electropolishing process of the present invention is based on a real time detection of the electric value (electric current or electric voltage) of the substrate to determine the status of the electropolishing process and the electropolishing endpoint. The electropolishing process is thus more effectively controlled to prevent the problems of dishing or erosion.

It is to be understood that both the foregoing general description and the following detailed description are exemplary, and are intended to provide further explanation of the invention as claimed.

### BRIEF DESCRIPTION OF DRAWINGS

The accompanying drawings are included to provide a further understanding of the invention, and are incorporated in and constitute a part of this specification. The drawings illustrate embodiments of the invention and, together with the description, serve to explain the principles of the invention. In the drawings,

FIGS. 1A to 1E are schematic diagrams illustrating the process flow for fabricating a metal interconnect according to one aspect of the present invention;

FIG. 2 is a schematic diagram illustrating the electropolishing apparatus used in the one aspect of the present invention; and

FIG. 3 is diagram illustrating the relationship between electropolishing time and current density.

### DETAILED DESCRIPTION

According to the present invention, the electropolishing of a metal layer is conducted under a fixed current or voltage. A voltage current detector is further installed in the electropolishing apparatus. As the electropolishing process proceeds to the barrier layer, noticeable changes occur in the current or voltage because of the difference in the resistance between the barrier layer and the metal layer. Based on the change in the saturated current or voltage, the endpoint of the electropolishing process is detected. A feedback control of the current or the voltage is conducted to terminate the supply of voltage or current and the electropolishing process. The features of the present invention are illustrated using the fabrication method for a metal interconnect (damascene) as an example.

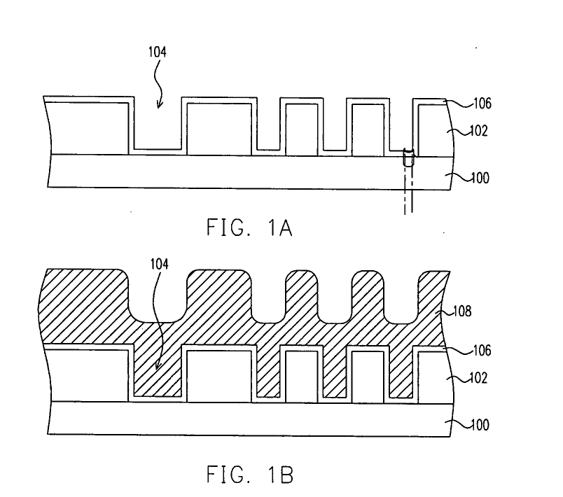

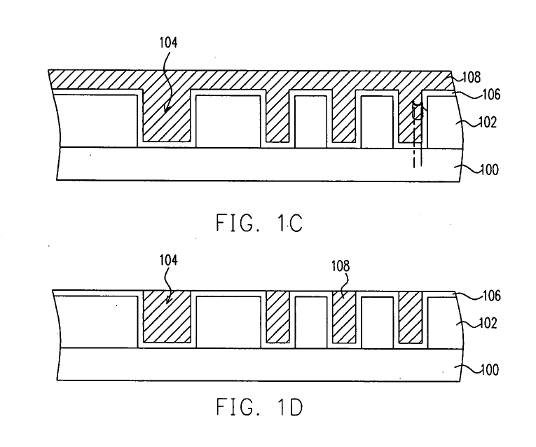

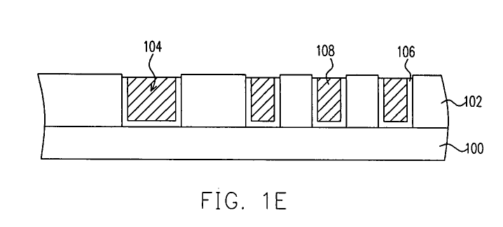

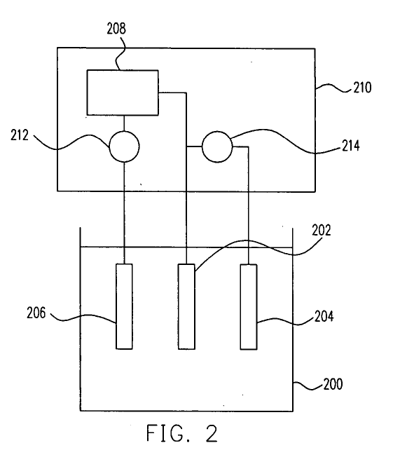

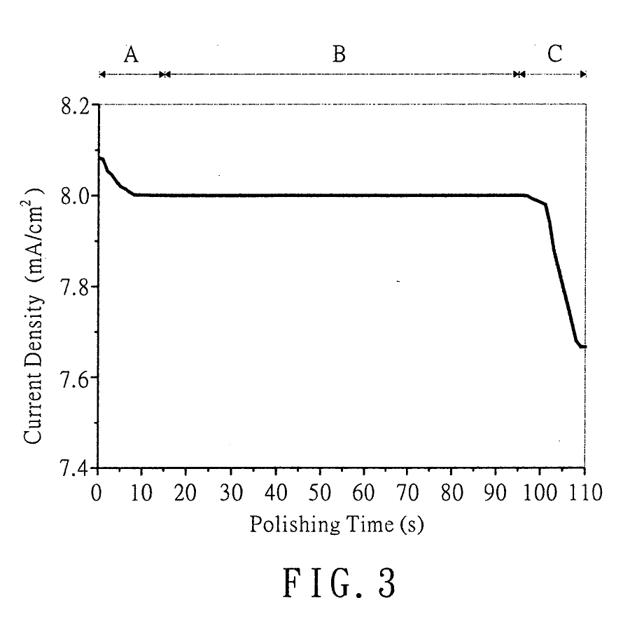

FIGS. 1A to 1E illustrate the process flow for fabricating a metal interconnect according to one aspect of the present invention. FIG. 2 is a schematic diagram illustrating the electrochemical apparatus used in the one aspect of the present invention. FIG. 3 is a diagram illustrating the relationship between polishing time and current density.

Referring to FIG. 1A, a substrate 100 is provided, wherein the substrate 100 is, for example, a silicon substrate. Further, the substrate 100 includes a semiconductor wafer already having semiconductor devices (not shown in Figure) or parts of a metal conductive line structure (not shown in Figure) formed thereon.

Thereafter, a dielectric layer 102 is formed over the substrate 100, wherein the dielectric layer 102 is formed with a material, such as, silicon oxide, low dielectric constant (low-K) material or other type of dielectric material. Forming the dielectric layer 102 includes performing, for example, chemical vapor deposition or spin-coating.

Thereafter, a portion of the dielectric layer 102 is removed to form an opening 104 in the dielectric layer 102, wherein the opening 104 exposes a portion of the substrate 100 surface. The exposed surface of the substrate 100 is going to be in contact with the conductive line, for example, devices in the substrate 100 or a part of the conductive line contact. The opening is, for example, a damascene opening of a dual damascene structure, such as, a trench, a via or a contact opening for a plug, or other opening of a damascene structure (only damascene opening is illustrated in the Figures). Forming the opening 104 includes performing, for example, photolithography and etching.

Thereafter, a barrier layer 106 is formed over the substrate 100, wherein the barrier layer 106 is conformal to the surface of the opening 104 and covers the dielectric layer 102. The barrier layer 106 includes tantalum nitride, titanium nitride or titanium silicon nitride material. Forming the barrier layer includes conducting a CVD, a PVD or an ion metal plasma (IMP) method. Generally, DC sputtering is performed to deposit a layer of tantalum on the wafer surface. The wafer is then placed in a nitrogen gas or an ammonium gas-containing environment at a high temperature to perform a nitridation reaction on tantalum to form tantalum nitride. The barrier layer can also be formed by performing reactive sputtering by using a metal target with a tantalum component, and a mixture of argon gas and nitrogen gas as a reaction gas to sputter tantalum through ion bombardment. Further reacting with nitrogen atoms that are formed through a dissociation reaction in plasma, tantalum nitride is formed and deposited on the wafer surface.

Referring to FIG. 1B, a metal layer 108 is formed over the barrier layer 106, filling the opening 104. The metal layer 108 is formed by, for example, physical vapor deposition (PVD), such as, electroplating or sputtering. The metal layer 108, such as, copper, is formed by, for example, electroplating using an electrolytic solution, such as, copper sulfate, sulfuric acid, a solution mixture of polyvinyl diglycol and 2-amino phenylthiazole.

Thereafter, the electropolishing process is conducted. In this aspect of the present invention, the electropolishing process is conducted in an electropolishing apparatus as shown in FIG. 2. As shown in FIG. 2, after connecting the wafer having the metal layer 108 already formed thereon to a working electrode 202, the working electrode 202, the reference electrode 204, the counter electrode 206 are all placed in an electrolytic tank 200. A power supply device 208 then provides an operating voltage (a fixed voltage) to the working electrode to start melting the surface of the metal layer 108. The end point detection device 210 is used to detect in real time the current flow of the wafer. The end point detection device 210 is, for example, a voltage current detector. This voltage current detector includes at least a voltage meter 212 and a current meter 214, wherein the electrolytic solution in the electrolytic tank 200 is, for example, a phosphoric acid solution.

As shown in FIG. 3, FIG. 3 is a diagram illustrating the relationship between polishing time and current density. When an electropolishing process (as shown in FIG. 1B) is performed on the metal layer 108 to planarize the rough surface or the height differences of the metal layer 108, current density decreases as polishing time increases until a saturation value (the A region in FIG. 3) is maintained. The electropolishing process performed on the metal layer 108 is then continued until the barrier layer 106 (as in FIG. 1D) is exposed. The current density changes and gradually reduces (region C in FIG. 3) because the resistance of the barrier layer 106 is different from that of the metal layer 108. Therefore, during the electropolishing process, the polishing endpoint can be identified by detecting in real time the current density of the substrate.

In other words, as the electropolishing process has proceeded to the barrier layer 106, the voltage current detector 210 detects the noticeable change in the current density of the wafer (current density reduces from saturation), which can be used as a feed back electric signal (voltage or current) Further, a control device (not shown) is used to discontinue the voltage supply to terminate the action of electropolishing.

Thereafter, as shown in FIG. 1E, chemical mechanical polishing process is performed to remove the portion of the metal layer 108 and the barrier 106 outside the opening 104 to complete the fabrication of a metal interconnect, which is well known to those skilled in the art and will be not be reiterated.

According to the present invention, as the electropolishing process is being performed, a fixed voltage or current is supplied to an electrolytic apparatus. Further using an end point detector (voltage current detector) to detect the real time changes of the electric value (changes of voltage or current) of the wafer, the electropolishing endpoint is identified. Since the beginning of the electropolishing process is simply to planarize the rough surface or the height differences of the metal layer, the electric value (voltage value or current value) of the wafer detected by the voltage current meter gradually drops to a saturation value. However, as the electropolishing process proceeds to expose a part of the polishing endpoint layer (barrier layer), the electric charge (voltage value or current value) of the wafer detected by the end point detector (voltage current detector) would drop further since the resistance of the barrier layer is different from that of the metal layer. Therefore, simply by detecting in real time the electric value (voltage value or current value), the status of the electropolishing process can be monitored to determine the endpoint of the electropolishing process.

According to the electropolishing endpoint detection method of the present invention, an endpoint detection device (voltage current detector) is installed on an electrolytic apparatus to detect the electric value (voltage value or current value) of the wafer that is being electropolished. Further, a control device (not shown) is used to feed back control the electric source supplier based on the electric value detected by the voltage current detector. The power supply is immediately discontinued when the electropolishing endpoint is detected. Since the electropolishing endpoint is effectively controlled, dishing or erosion can be prevented. Further, a small modulated signal (for example, a waveform) can also added to the bias (voltage current detector) to control more accurately the process endpoint and to enhance the sensitivity of the voltage current detector.

Copper is used as an example for the metal layer in this aspect of the present invention. Other metal material is also applicable in the electropolishing endpoint detection method of the present invention. As long as the material for the metal layer is different from that for the polishing end point layer, the electropolishing endpoint detection of method can be applied.

It will be apparent to those skilled in the art that various modifications and variations can be made to the structure of the present invention without departing from the scope or spirit of the invention. In view of the foregoing, it is intended that the present invention cover modifications and variations of this invention provided they fall within the scope of the following claims and their equivalents.

1. An electrochemical polishing endpoint detection method, the method comprising:
providing a substrate, wherein the substrate comprises a dielectric layer with at least an opening formed therein, a barrier layer and a metal layer, wherein the barrier layer is conformal to the opening covers the dielectric layer and the metal layer covers the barrier layer and fills up the opening;
placing the substrate in an electropolishing apparatus;
providing a fixed voltage or current to the substrate to perform an electropolishing on the metal layer and monitoring in real time an electric value of the substrate;
detecting an electropolishing endpoint of the electropolishing as soon as the barrier layer is exposed and detecting a noticeable change of the electric value of the substrate; and
discontinuing a power supply to the substrate and terminating the electrochemical polishing process.

2-3. (canceled)

4. An end point detection method for an electropolishing process, which is applicable in an electropolishing apparatus, wherein the electropolishing apparatus comprises at least an electrolytic tank, a power supply, an endpoint detection device, the method comprising:
providing a substrate, wherein the substrate comprises at least a first material layer and a second material layer, and the first material layer comprises at least an opening, while the second material layer fills the opening and covers the first material layer,
placing the substrate in the tank and providing a fixed voltage to the substrate with the power supply to perform the electropolishing process on the second material layer;
monitoring an electric charge of the substrate using the endpoint detection device;
detecting an end point of the electropolishing process as soon as the second material layer is exposed.

5. The method of claim 4, wherein a material of the first material layer is different from that of the second material layer in order to use the first material layer as an electrochemical polishing endpoint layer.

6. The method of claim 4, wherein the step of the end point comprises detecting a noticeable change of the electric charge of the substrate and the method further comprises:
discontinuing an electric power supply to the substrate; and
terminating the electropolishing process.

7. The method of claim 4, wherein the method further comprises installing a signal modulator in the endpoint detection device to control the endpoint detection.

8-10. (canceled)
